(19) United States
(12) Patent Application Publication
(10) Pub. No.: US 2025/0338493 A1
(43) Pub. Date: Oct. 30, 2025

(54) SEMICONDUCTOR CIRCUIT STRUCTURE WITH COMPOSITE SHALLOW TRENCH ISOLATION REGION FOR HEAT DISSIPATION AND METHOD FOR FORMING THE SAME

(71) Applicant: Invention and Collaboration Laboratory, Inc., Taipei City (TW)

(72) Inventors: Chao-Chun LU, Hsinchu (TW); Chun-Nan LU, Hsinchu (TW); Li-Ping HUANG, Hsinchu (TW)

(73) Assignee: Invention and Collaboration Laboratory, Inc., Taipei City (TW)

(21) Appl. No.: 19/190,483

(22) Filed: Apr. 25, 2025

Related U.S. Application Data
(60) Provisional application No. 63/638,981, filed on Apr. 26, 2024.
(60) Provisional application No. 63/661,914, filed on Jun. 20, 2024.

(51) Int. Cl. H10B 12/00; H01L 21/763; H01L 23/373

(52) U.S. Cl. CPC H10B 12/50; H01L 21/763; H01L 23/3738; H10B 12/053; H10B 12/09; H10B 12/34; H10B 12/488

(57) ABSTRACT

A semiconductor circuit structure includes a semiconductor substrate; a first set of active regions within the semiconductor substrate; and a fist shallow trench isolation (STI) region surrounding the first set of the active regions. Wherein the first STI region includes an inner section disposed within a gap among the first set of active regions and an outer section not disposed within the gap. Wherein the inner section includes a first portion with a thermal conductivity semiconductor material and a second portion without the thermal conductivity semiconductor material, and a thermal conductivity of the thermal conductivity semiconductor material is higher than that of SiO₂.

This application claims the benefit of U.S. provisional applications Ser. No. 63/638,981 filed Apr. 26, 2024, Ser. No. 63/661,914 filed Jun. 20, 2024 and the subject matter of which is incorporated herein by reference.

### BACKGROUND OF THE DISCLOSURE

### Field of the Disclosure

The present invention relates to a semiconductor device and method for manufacturing the same, and particularly to a transistor structure surrounded by a composite shallow trench isolation region having semiconductor material for heat dissipation and method for manufacturing the same.

### Description of the Related Art

Monolithic integration of silicon devices for integrated circuits (IC) has achieved realization of more than 50 billions of transistors on a die in the year of 2021, which has been named as an era of GSI (Gigabyte-Scale Integration, i.e. Achieving more than billions of transistors on a die) from VLSI (Very Large Scale Integration having more than millions of transistors on a die). Such accomplishments of making much higher integration capacity of transistors on a die have sharply enabled more powerful Microsystems with significantly improved PPAC (higher Performance, better Power Managing capability, effective usage of Area and lower Cost per bit), thus creating many powerful chips such as CPU, GPU, FPGA, SOC, SRAM, DRAM, etc., which enhances System capabilities so as to continually support Moore's Law which formed a base to create an exponential Economic growth.

Moreover, the monolithic integration capability of a Silicon chip has grown from GSI (Giga Scale Integration: Over billions of transistors on a die) toward TSI (Tera Scale Integration: Trillions of transistors on a die) soon and chip performance is being improved significantly.

However, the power consumption of running such a huge number of transistors is increasing sharply, which elevates adversely the junction temperature of transistors and thus the entire chip temperature due to current limited heat-dissipation capability (e.g. Thermal conductivity index of silicon-dioxide (SiO₂) is very low. This material and device structural problem causes a negative cyclic effect, that is, the elevated higher die temperature slows down the speed of transistors, and then inevitably enforcing the design to increase higher power to circuitry in order to accelerate the transistor performance but this mechanism causes badly raising the die temperature, and consequently the heat-dissipation problem is getting worse.

Actually this insufficient heat dissipation problem causing higher temperature to chip operation is regarded as the worst problem for the entire chip industry, which should be solves to avoid a major roadblock to a larger number of device integration on a die. The progress of reducing the temperature of a GSI chip is not improved well as it should be, however. Actually as the transistor dimensions must be made smaller as the technology node is being scaled further (e.g. the minimum feature size is being scaled from 7 nm to 5 nm, then to 3 nm and so forth), the percentage of oxide coverage to the total transistor size is getting higher and the thermal dissipation capability across the device junctions is not further being aggregated. Though a lot of heat dissipation methods are created, for example, covering the entire chip with higher heat-removal pad outside the chip or using a liquid cooling circulation outside the packaged chip, etc., all of which are very expensive but returned with low efficiency for effectively reducing the junction temperatures of transistors.

### SUMMARY OF THE DISCLOSURE

One object of the present disclosure is to provide a semiconductor circuit structure, wherein the semiconductor circuit structure includes a semiconductor substrate; a first set of active regions within the semiconductor substrate; and a first shallow trench isolation (STI) region surrounding the first set of the active regions. Wherein the first STI region includes an inner section disposed within a gap among the first set of active regions and an outer section not disposed within the gap. Wherein the inner section includes a first portion with a thermal conductivity semiconductor material and a second portion without the thermal conductivity semiconductor material, and a thermal conductivity of the thermal conductivity semiconductor material is higher than that of SiO₂.

According to one embodiment of the present disclosure, the semiconductor substrate has an original surface, and a top surface of the thermal conductivity semiconductor material is lower than the original surface between 5 nm to 30 nm.

According to one embodiment of the present disclosure, the thermal conductivity semiconductor material comprises silicon with an average grain size ranging from 0.1 μm to 2 μm.

According to one embodiment of the present disclosure, within the first STI region, there is no more than three grains of silicon along a depth direction of the first STI region.

According to one embodiment of the present disclosure, the thermal conductivity semiconductor material is selected form silicon, silicon carbide (SiC), boron nitride (BN), aluminum nitride (AlN), and a combination thereof.

According to one embodiment of the present disclosure, the first STI region further includes a dielectric layer to isolate the thermal conductivity semiconductor material from the semiconductor substrate.

According to one embodiment of the present disclosure, the first portion of the inner section of the first STI region is horizontally separate from the second portion of the inner section of the first STI region, and a metal connection line crosses over the first set of active regions and the second portion of the inner section of the STI region.

According to one embodiment of the present disclosure, the semiconductor circuit structure is a DRAM circuit comprising a memory cell circuit and a peripheral circuit, and the first set of the active regions are within the memory cell circuit; wherein an access transistor within one of the first set of the active regions includes a gate recess, a gate dielectric layer, gate electrode, a source region and a drain region. The gate recess extends into the semiconductor substrate from the original surface. The gate dielectric layer covers on a bottom and sidewalls of the gate recess. The gate electrode is formed in the gate recess and surrounded by the gate dielectric layer. The source region is adjacent to one side of the gate electrode. The drain region is adjacent to another side of the gate electrode.

According to one embodiment of the present disclosure, the metal connection line is a word line connected to the gate electrode of the access transistor.

According to one embodiment of the present disclosure, the peripheral circuit comprises a second set of active regions and a second STI region surrounding the second set of active regions; wherein all of the second STI region comprises the thermal conductivity semiconductor material, and all of the outer section of the first STI region comprises the thermal conductivity semiconductor material.

Another object of the present disclosure is to provide a method for fabricating a semiconductor circuit structure, wherein the method includes steps as follows: A semiconductor substrate is provided. A fist shallow trench isolation (STI) region surrounding a first set of the active regions is formed within the semiconductor substrate. A transistor is formed within one of the first set of the active regions. Wherein the first STI region including an inner section disposed within a gap among the first set of active regions and an outer section not disposed within the gap among the first set of active regions. Wherein the inner section includes a first portion with a thermal conductivity semiconductor material and a second portion without the thermal conductivity semiconductor material, and a thermal conductivity of the thermal conductivity semiconductor material is higher than that of SiO₂.

According to one embodiment of the present disclosure, the forming of the first STI region includes steps of forming a shallow trench extending into the semiconductor substrate from an original surface of the semiconductor substrate to define the first set of active regions; filling an oxide structure within the shallow trench; removing at least portion of the oxide structure in the first portion of the inner section and the outer section to form at least one hollowed trench; forming a dielectric layer on sidewalls and a bottom of the at least one hollowed trench; and filling the at least one hollowed trench with the thermal conductivity semiconductor material, wherein the thermal conductivity semiconductor material is isolated from the semiconductor substrate by the dielectric layer.

According to one embodiment of the present disclosure, the step of filling the at least one hollowed trench with the thermal conductivity semiconductor material includes: filling the at least one hollowed trench with an amorphous semiconductor material; curing the amorphous semiconductor material by an ultraviolet light; and performing a laser annealing or a rapid thermal annealing against the cured amorphous semiconductor material to form the thermal conductivity semiconductor material.

According to one embodiment of the present disclosure, the thermal conductivity semiconductor material is selected from a group consisting of SiC, BN, AlN, and arbitrary combinations thereof.

According to one embodiment of the present disclosure, the semiconductor circuit structure is a DRAM circuit including a memory cell circuit and a peripheral circuit, and the first set of the active regions are within the memory cell circuit; wherein the transistor is an access transistor within one of the first set of the active regions. Wherein the forming of the access transistor includes steps of forming a gate recess extending into the one of the first set of the active regions of the semiconductor substrate from the original surface; forming a gate dielectric layer covering on a bottom and sidewalls of the gate recess; forming a gate electrode in the gate recess and surrounded by the gate dielectric layer; forming a source region adjacent to one side of the gate electrode and; forming a drain region adjacent to another side of the gate electrode.

According to one embodiment of the present disclosure, the first portion of the inner section of the first STI region is horizontally separate from the second portion of the inner section of the first STI region, and a metal connection line crosses over the first set of active regions and the second portion of the inner section of the first STI region.

According to one embodiment of the present disclosure, the metal connection line is a word line connected to the gate electrode of the access transistor.

According to one embodiment of the present disclosure, the peripheral circuit includes a second set of active regions and a second STI region surrounding the second set of active regions; wherein all of the second STI region includes the thermal conductivity semiconductor material, and all of the outer section of the first STI region includes the thermal conductivity semiconductor material.

### BRIEF DESCRIPTION OF THE DRAWINGS

The above and other aspects of the disclosure will become better understood with regard to the following detailed description of the preferred but non-limiting embodiment(s). The following description is made with reference to the accompanying drawings:

FIG. 1A(1) is a top view illustrating the structure after the STI structure is formed in the semiconductor substrate to define at least one active area;

FIG. 1A(2), FIG. 1A(3), FIG. 1A(4), FIG. 1A(5) are cross-sectional views taken alone the cutting-line CA1, CA2, CA3 and CA4 respectively, as depicted in FIG. 1A(1); and FIG. 1A(6) is a cross-sectional view within the peripheral circuit region of a DRAM circuit structure shown in FIG. 1A(1);

FIG. 1B(1) is a top view illustrating the structure after the recess gate (RG) pattern is defined;

FIG. 1B(2), FIG. 1B(3), FIG. 1B(4), and FIG. 1B(5) are cross-sectional views taken alone the cutting-line CB1, CB2, CB3, and CB4 respectively, as depicted in FIG. 1B(1); and FIG. 1B(6) is a cross-sectional view within the peripheral circuit region of the DRAM circuit structure shown in FIG. 1B(1);

FIG. 1C(1) is a top view illustrating the structure after the RG pattern is transferred to the remaining nitride layer;

FIG. 1C(2), FIG. 1C(3), FIG. 1C(4), and FIG. 1C(5) are cross-sectional views taken alone the cutting-line CC1, CC2, CC3, CC4, and CC5 respectively, as depicted in FIG. 1C(1); and FIG. 1C(6) is a cross-sectional view within the peripheral circuit region of the DRAM circuit structure shown in FIG. 1C(1);

FIG. 1D(1) is a top view illustrating the structure after the at least one hollowed trench is formed in the shallow trenches;

FIG. 1D(2), FIG. 1D(3), FIG. 1D(4), and FIG. 1D(5) are cross-sectional views taken alone the cutting-line CD1, CD2, CD3, and CD4 respectively, as depicted in FIG. 1D(1); and FIG. 1D(6) is a cross-sectional view within the peripheral circuit region of the DRAM circuit structure shown in FIG. 1D(1);

FIG. 1E(1) is a top view illustrating the structure after the at least one thermal conductivity region is formed in the at least one hollowed trench;

FIG. 1E(2), FIG. 1E(3), FIG. 1E(4), and FIG. 1E(5) are cross-sectional views taken alone the cutting-line CE1, CE2, CE3, and CE4 respectively, as depicted in FIG. 1E(1); and FIG. 1E(6) is a cross-sectional view within the peripheral circuit region of the DRAM circuit structure shown in FIG. 1E(1);

FIG. 1F(1) is a top view illustrating the structure after the oxide hard mask layer and another amorphous carbon(a-C) layer are formed;

FIG. 1F(2), FIG. 1F(3), FIG. 1F(4), and FIG. 1F(5) are cross-sectional views taken alone the cutting-line CF1, CF2, CF3, and CF4 respectively, as depicted in FIG. 1F(1); FIG. 1F(6) is a cross-sectional view within the peripheral circuit region of the DRAM circuit structure shown in FIG. 1F(1);

FIG. 1G(1) is a top view illustrating the structure after the plurality of gate recesses and the plurality of word line trenches are formed;

FIG. 1G(2), FIG. 1G(3), FIG. 1G(4), and FIG. 1G(5) are cross-sectional views taken alone the cutting-line CG1, CG2, CG3, and CG4 respectively, as depicted in FIG. 1G(1); and FIG. 1G(6) is a cross-sectional view within the peripheral circuit region of the DRAM circuit structure shown in FIG. 1G(1).

FIG. 1H(1) is a top view illustrating the semiconductor circuit structure is formed;

FIG. 1H(2), FIG. 1H(3), FIG. 1H(4), and FIG. 1H(5) are cross-sectional view taken alone the cutting-line CH1, CH2, CH3, and CH4 respectively, as depicted in FIG. 1H(1); and FIG. 1H(6) is a cross-sectional view within the peripheral circuit region of the semiconductor circuit structure (the DRAM circuit structure) shown in FIG. 1H(1).

### DETAILED DESCRIPTION OF THE DISCLOSURE

The present disclosure provides a semiconductor circuit structure and method for forming the same for effectively reducing the junction temperatures of transistors. The above and other aspects of the disclosure will become better understood by the following detailed description of the preferred but non-limiting embodiment(s). The following description is made with reference to the accompanying drawings.

Several embodiments of the present disclosure are disclosed below with reference to accompanying drawings. However, the structure and contents disclosed in the embodiments are for exemplary and explanatory purposes only, and the scope of protection of the present disclosure is not limited to the embodiments. It should be noted that the present disclosure does not illustrate all possible embodiments, and anyone skilled in the technology field of the disclosure will be able to make suitable modifications or changes based on the specification disclosed below to meet actual needs without breaching the spirit of the disclosure. The present disclosure is applicable to other implementations not disclosed in the specification.

### Embodiment 1

The present embodiment discloses a semiconductor circuit structure 100 with high thermal dissipation capability. A DRAM circuit structure including memory cell circuit and peripheral circuit is used as an example. Detailed steps of the manufacturing method of the semiconductor circuit structure 100 as follows:
Step S11: A semiconductor substrate 101 is provided;
Step S12: A composite isolation structure 102 is formed in the semiconductor substrate 101 to define at least one active area 101A within the semiconductor substrate 101; wherein the composite isolation structure 102 includes a high thermal conductivity region 106 with a thermal conductivity higher than a thermal conductivity of silicon oxide; wherein the Step S12 for forming the composite isolation structure 102 includes Sub-steps S121-S124:
   Sub-step S121: A shallow trench isolation (STI) region with a STI structure 103 is formed, the STI structure 103 extends into the semiconductor substrate 101 from an original surface 101S of the semiconductor substrate 101 to define the at least one active area 101A;
   Sub-step S122: All or a portion of the STI structure 103 is removed to form at least one hollowed trench 104;
   Sub-step S123: A dielectric layer 105 is formed on sidewalls 104S and a bottom 104B of the at least one hollowed trench 104; and
   Sub-step S124: The at least one hollowed trench 104 is filled with high thermal conductivity material to form the high thermal conductivity region 106 electrically isolated from the semiconductor substrate 101 by the dielectric layer 105;
Step S13: At least one transistor 107 is formed based on the at least one the active area 101A; wherein the Step S13 for forming the at least one transistor 107 includes Sub-steps S131-S134:
   Sub-step S131: At least one gate recess 108 is formed, extended into the at least one active area 101A of the semiconductor substrate 101 from the original surface 101S);
   Sub-step S132: A gate dielectric layer 107L is formed covering on a bottom and sidewalls of the at least one gate recess 108;
   Sub-step S133: At least one gate electrode 107E is formed in the at least one gate recess 108; and
   Sub-step S134: At least one source region 107S and one drain region 107D are formed in the at least one active area 101A, adjacent to the at least one gate electrode.

Referring to Step S11: A semiconductor substrate 100 is provided. In some embodiments of the present disclosure, the semiconductor substrate 101 may be a silicon-containing substrate, such as a silicon (Si) wafer or a silicon-on-insulator (SOI) substrate. In some other embodiments of the present disclosure, the semiconductor substrate 101 may be made of other types of semiconductor materials, such as silicon carbide (SiC), germanium (Ge), or compound semiconductor materials, such as gallium arsenide (GaAs). In the present embodiment, the semiconductor substrate 101 may be a silicon wafer.

Referring to Step S12: A composite isolation structure 102 is formed in the semiconductor substrate 101 to define at least one active area 101A within the semiconductor substrate 101; wherein the composite isolation structure 102 includes a high thermal conductivity region 106 with a thermal conductivity higher than a thermal conductivity of silicon oxide. The Step S12 for forming the composite isolation structure 102 includes Sub-steps S121-S124 as follows:

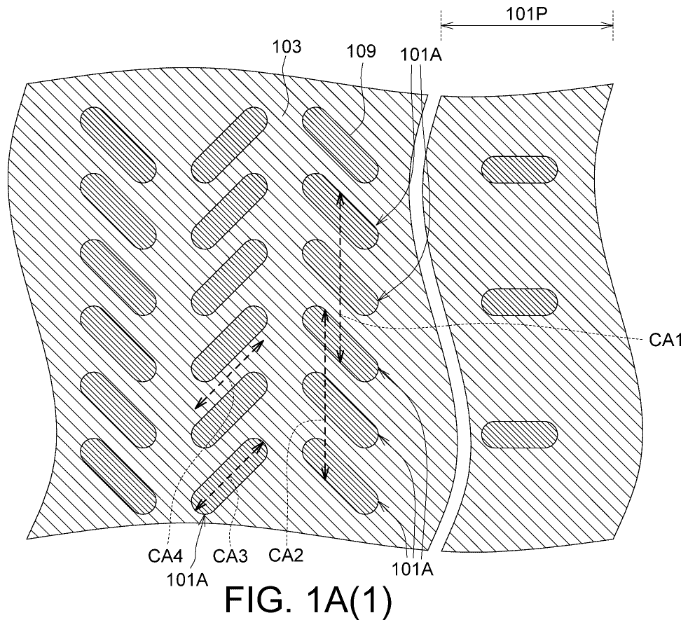

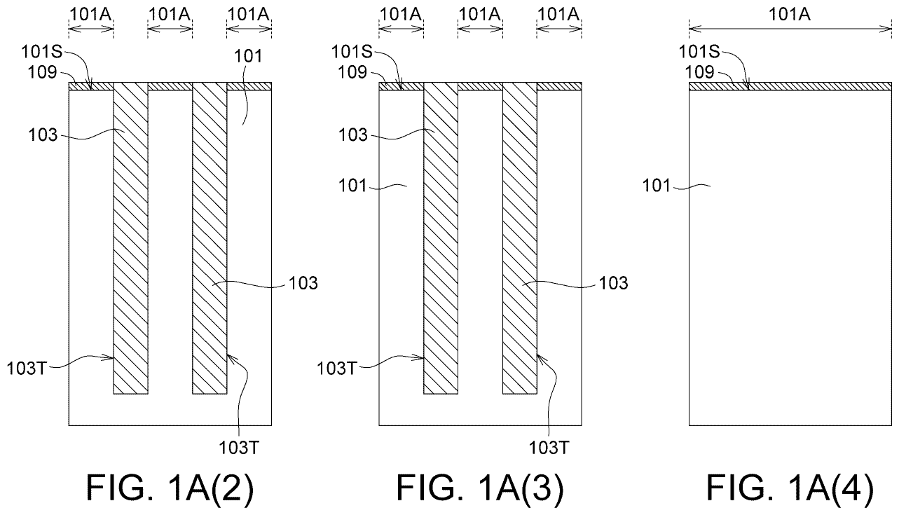

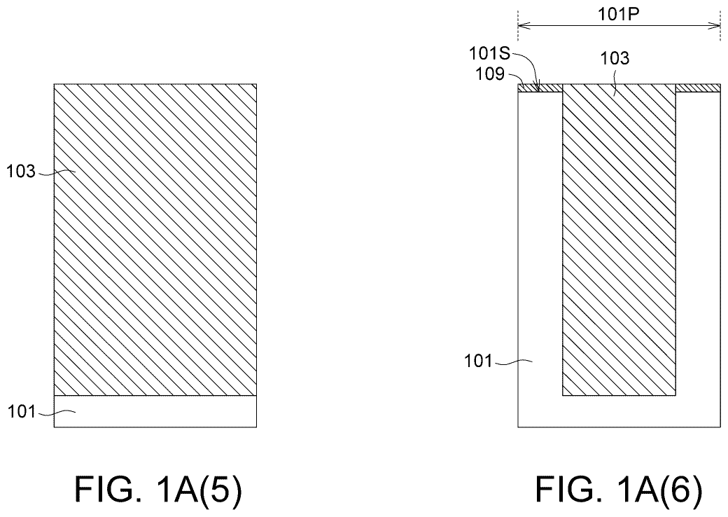

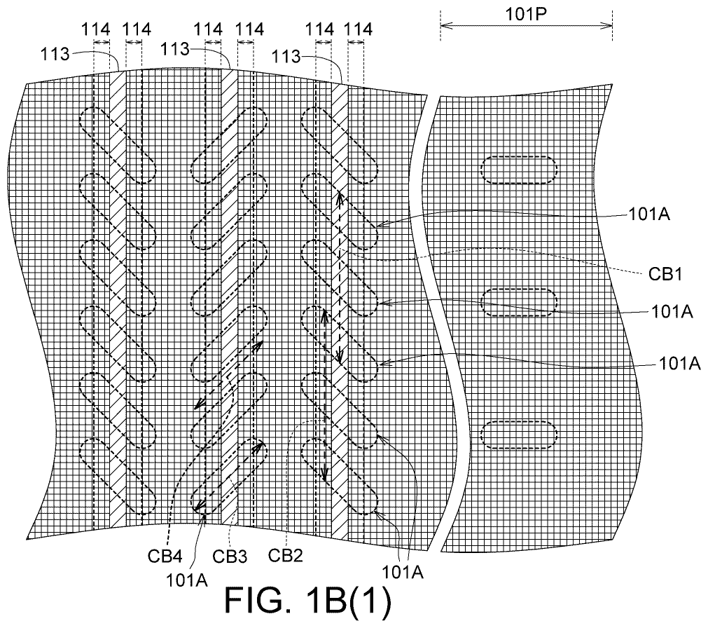

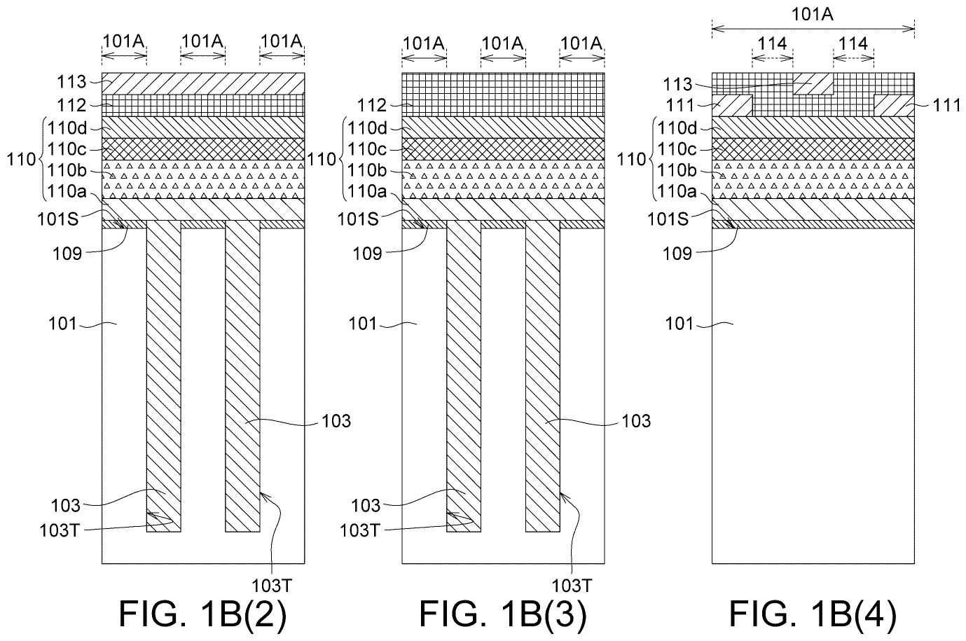

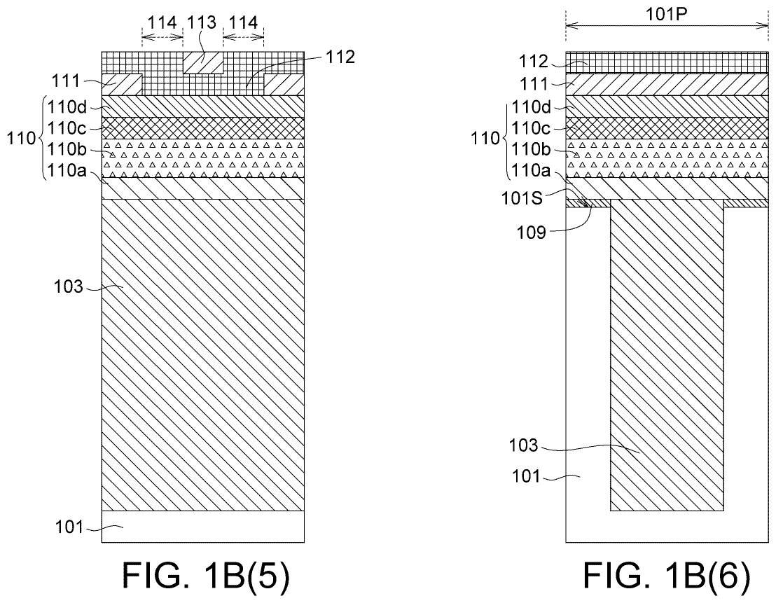

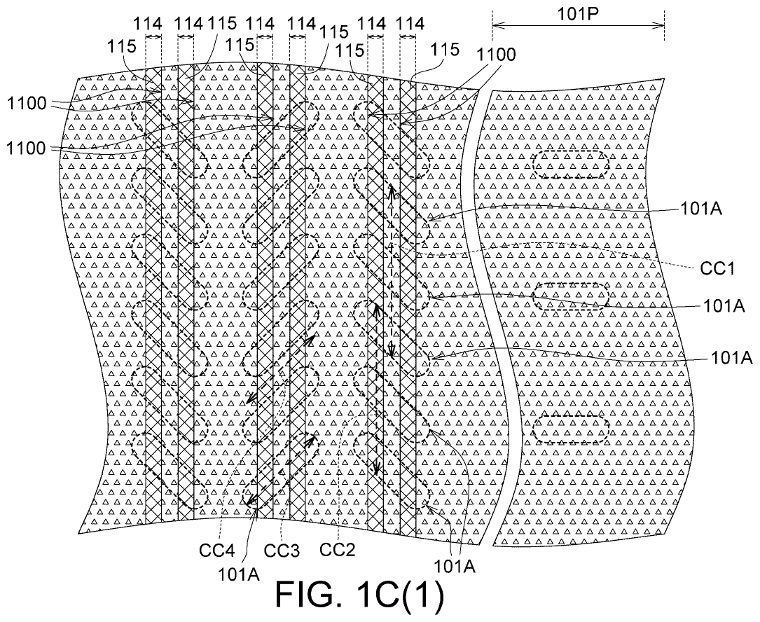

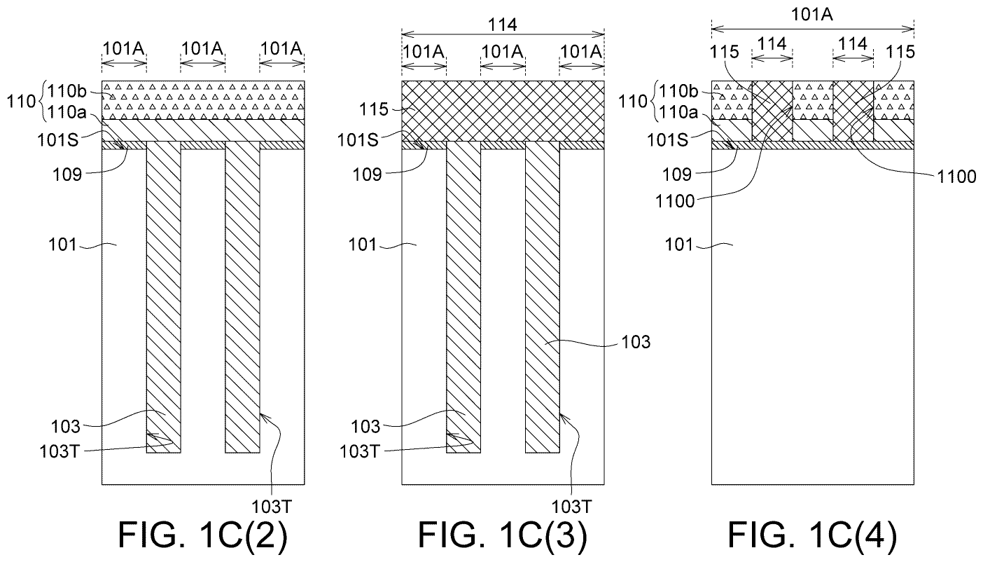

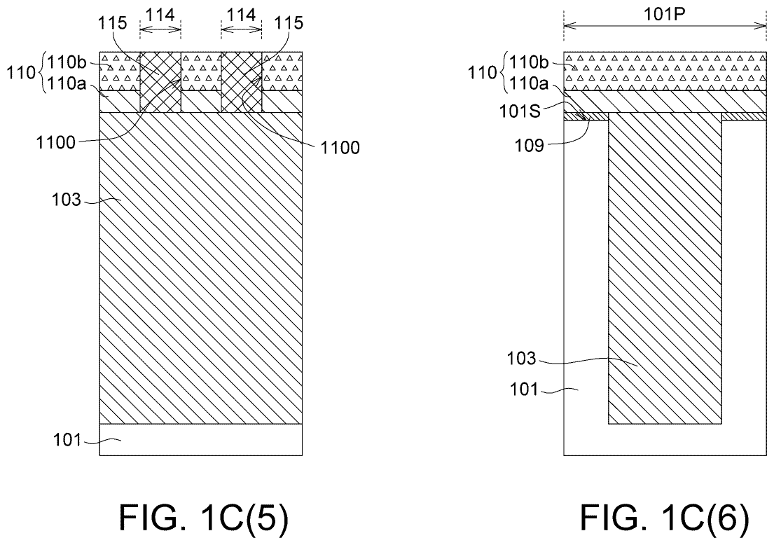

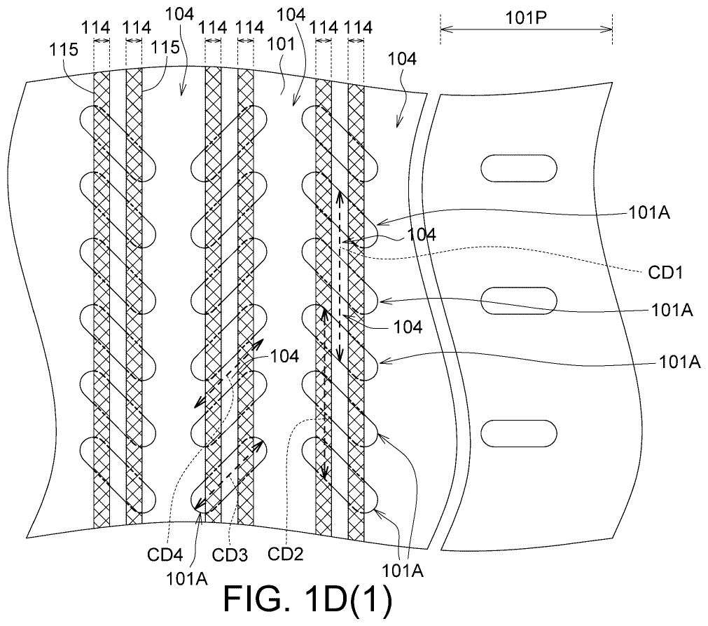

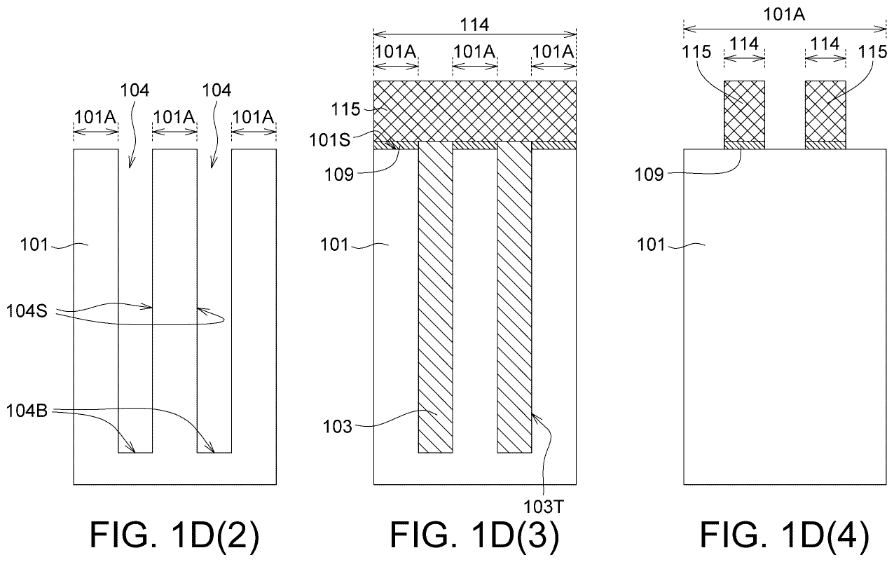

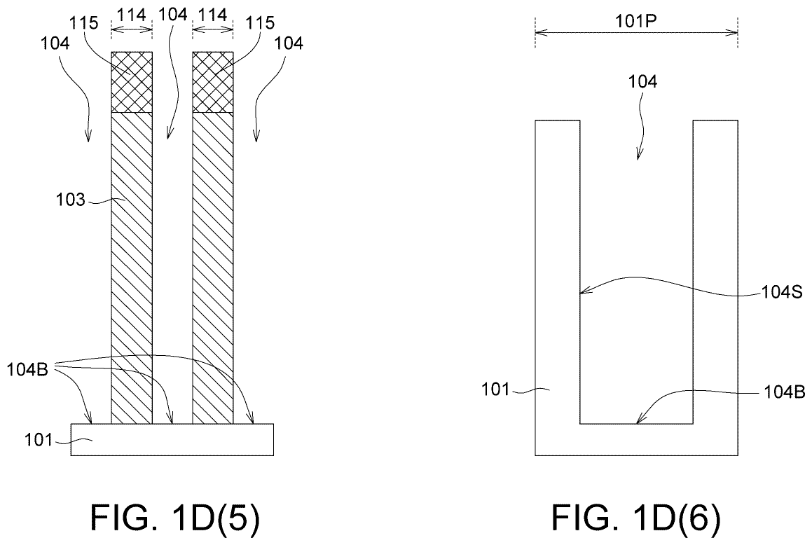

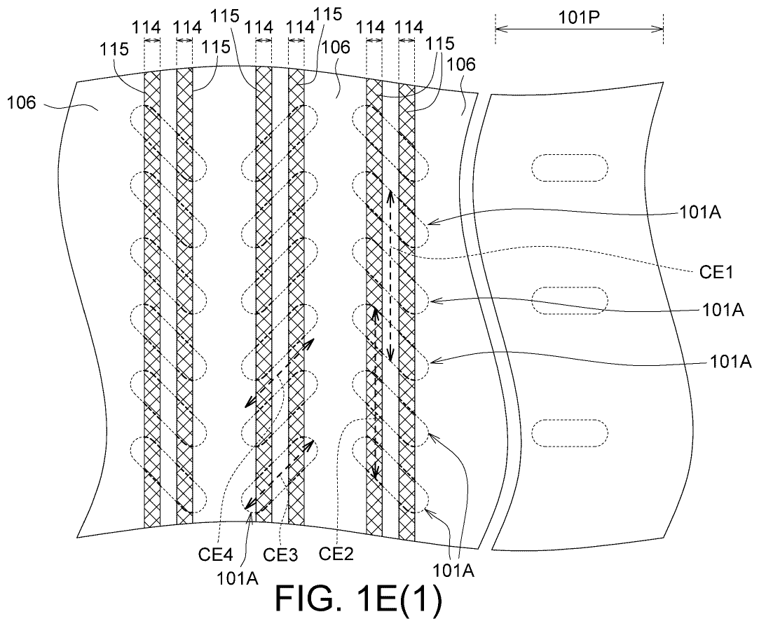

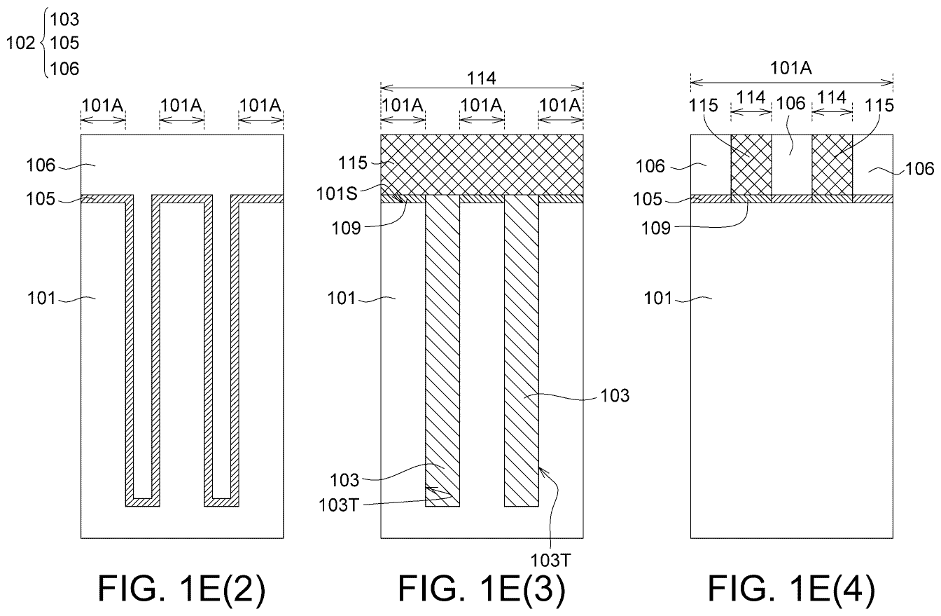

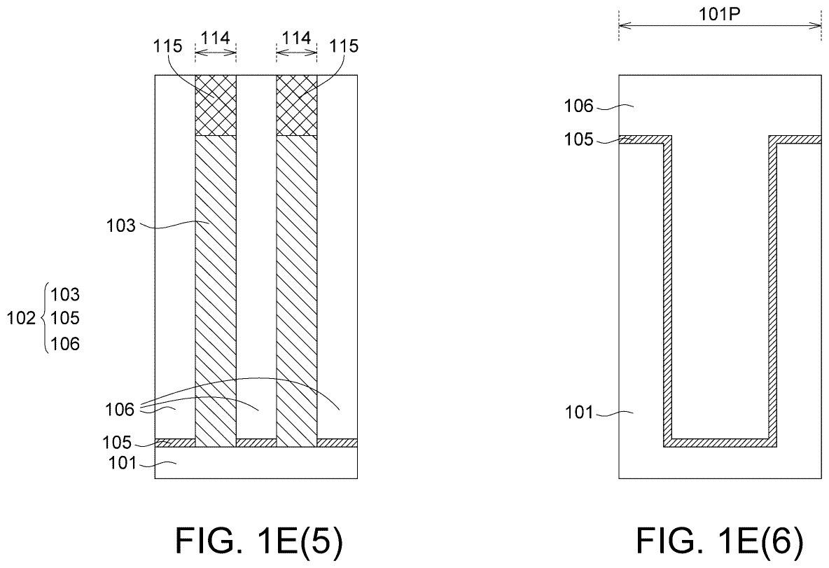

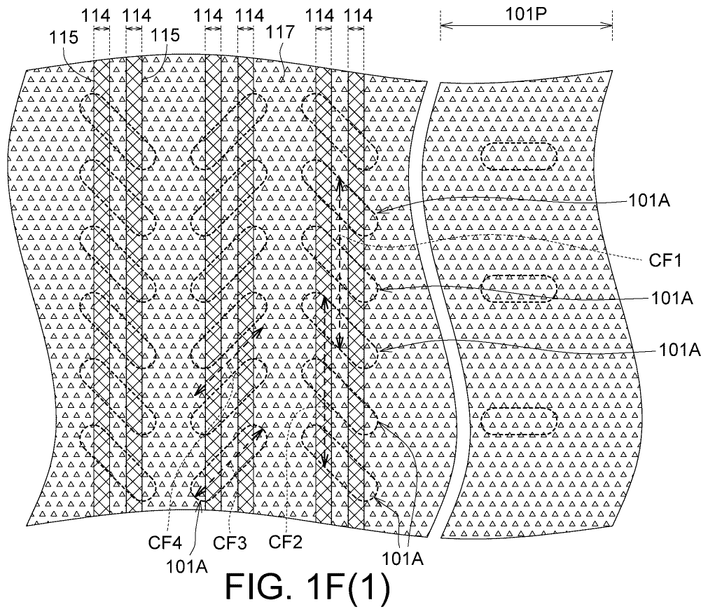

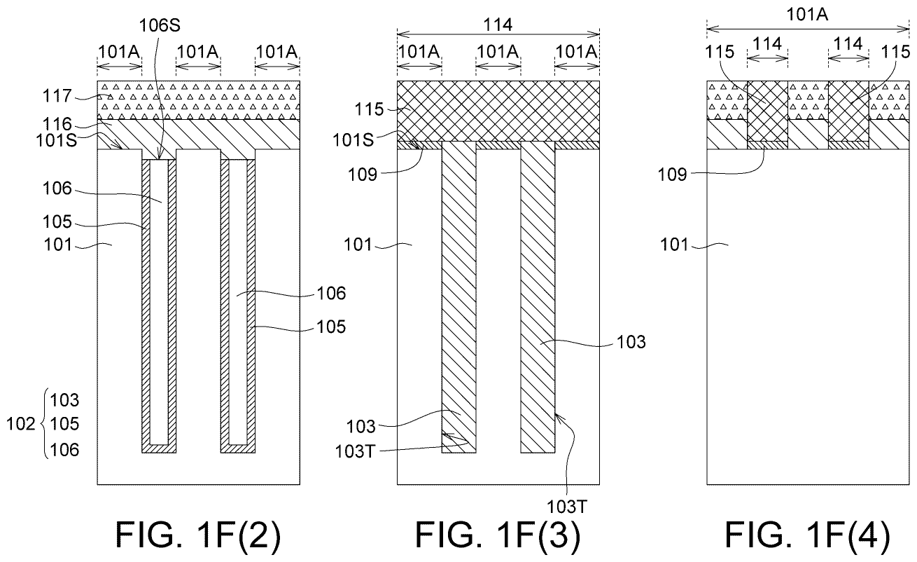

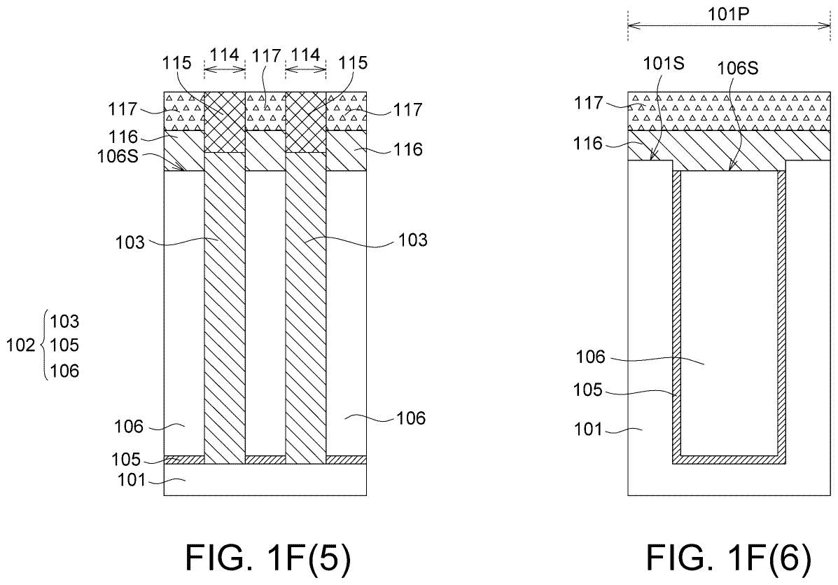

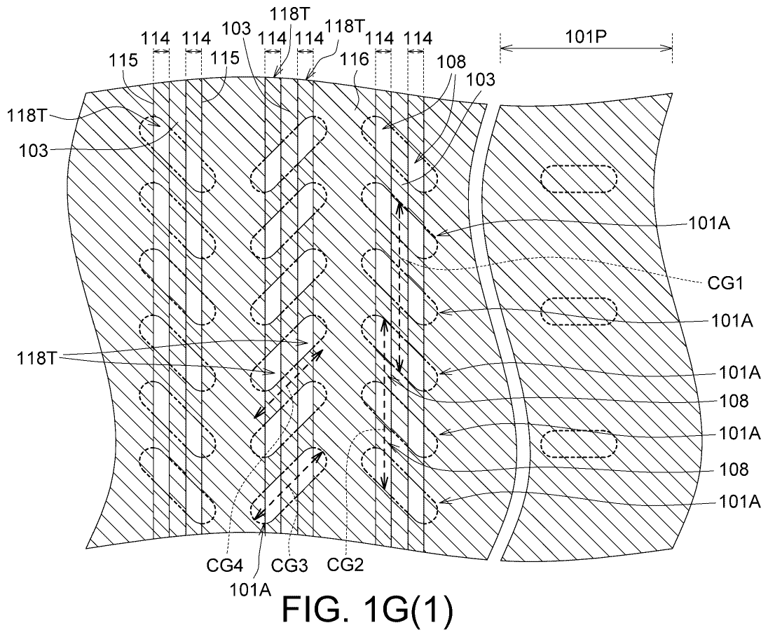

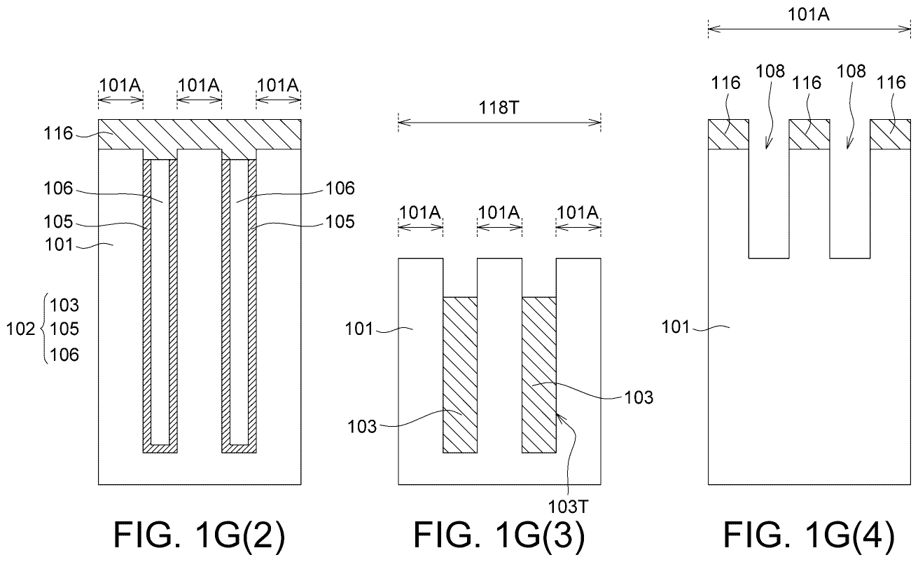

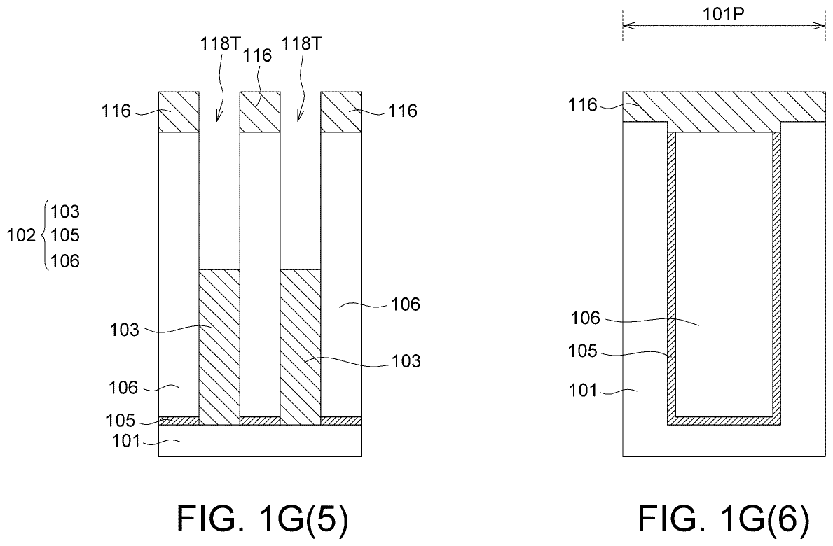

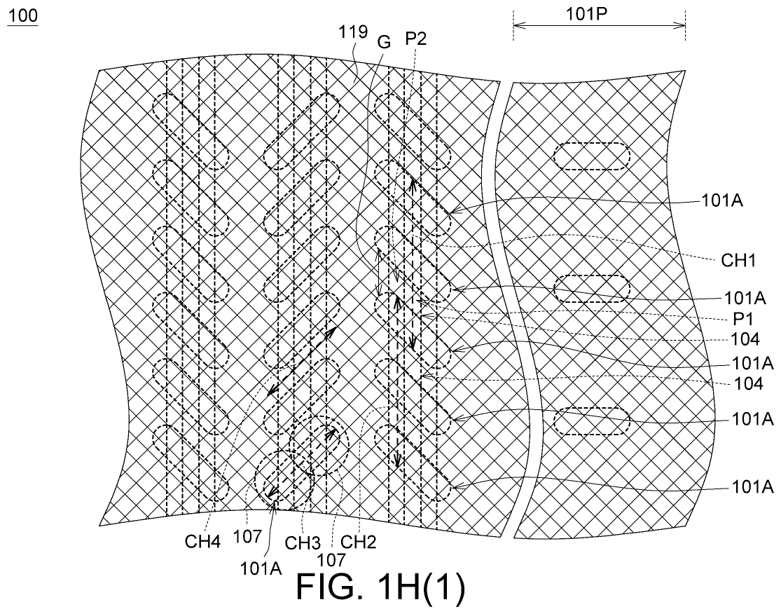

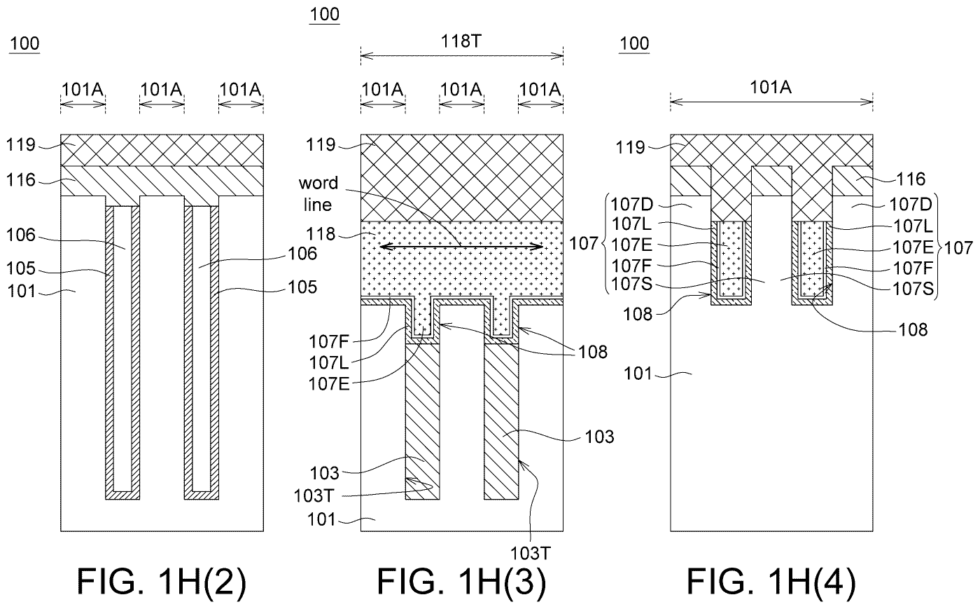

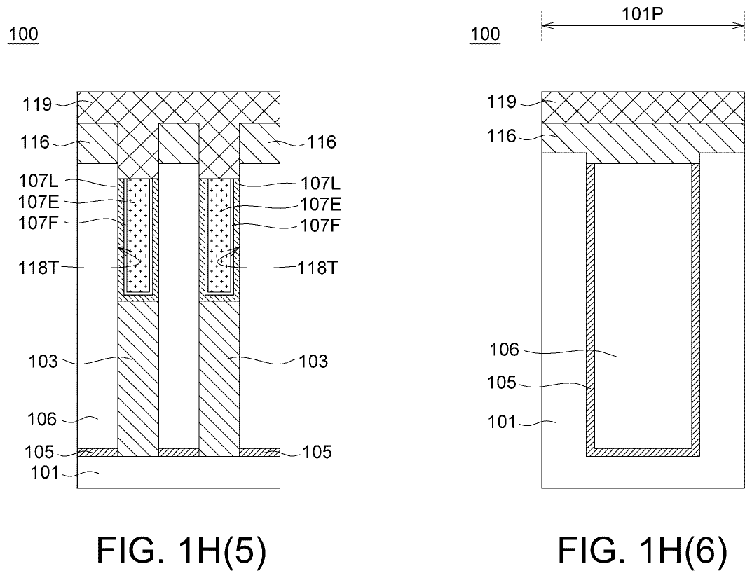

Referring to Sub-step S121, A STI region is defined and the STI region comprising a STI structure 103 is formed extending into the semiconductor substrate 101 from an original surface 101S of the semiconductor substrate 101 to define the at least one active area 101A. Using DRAM circuit structure including memory cell circuit region and peripheral circuit region 101P as an example, FIG. 1A(1) is a top view illustrating the structure within the memory cell circuit region after the STI structure 103 is formed and extending into the semiconductor substrate 101 to define at least one active area 101A; FIG. 1A(2) is a cross-sectional view taken alone the cutting-line CA1 as depicted in FIG. 1A(1); FIG. 1A(3) is a cross-sectional view taken alone the cutting-line CA2 as depicted in FIG. 1A(1); FIG. 1A(4) is a cross-sectional view taken alone the cutting-line CA3 as depicted in FIG. 1A(1); FIG. 1A(5) is a cross-sectional view taken alone the cutting-line CA4 as depicted in FIG. 1A(1); and FIG. 1A(6) is a cross-sectional view within the peripheral circuit region 101P of the DRAM circuit structure shown in FIG. 1A(1).

The forming of the STI structure 103 includes steps as follows: Firstly, an etching process using a patterned pad dielectric layer 109 (including a patterned pad oxide layer and a patterned pad nitride layer (not shown)) as an etching mask is performed to remove parts of silicon material of a semiconductor substrate 101 to create a plurality of shallow trenches 103T, and the shallow trenches 103T are filled with a dielectric material to define a plurality of fin structures in the semiconductor substrate 101. In some embodiments, the shallow trenches 103T are filled with silicon oxide, and each of remaining semiconductor structures may serve as an active area 101A. In the present embodiment, the plurality of active areas 101A are arranged in an array, as shown in FIG. 1A(1) for memory cell circuit. Thereafter, well region implantation and channel implantation could be made.

Next referring to Sub-step S122, a portion of the STI structure 103 is removed to form at least one hollowed trench 104. The forming of the at least one hollowed trench 104includes steps as follows:

Firstly, a hard mask layer 110, including a first silicon oxide 110a, an amorphous carbon (a-C) layer 110b, a silicon nitride layer 110c and a second silicon oxide 110d, is deposited on the pad dielectric layer 109. A first patterned bottom anti-reflective coating (BARC) 111 is formed on the hard mask layer 110. After a molecular layer deposition (MLD) 112 is formed and then planarzed on the first patterned BARC 111, a second patterned BARC 113 (surrounded by another MLD the same with MLD 112) is formed on the MLD 112. Thereby, recess gate patterns 114 (or word line patterns in the memory cell circuit region of the DRAM circuit structure are defined by a self-aligned double patterning (SADP) technique.

As shown in FIGS. 1B(1)-1B(6), FIG. 1B(1) is a top view illustrating the structure after the recess gate (RG) pattern 114 is defined; FIG. 1B(2) is a cross-sectional view taken alone the cutting-line CB1 as depicted in FIG. 1B(1); FIG. 1B(3) is a cross-sectional view taken alone the cutting-line CB2 as depicted in FIG. 1B(1); FIG. 1B(4) is a cross-sectional view taken alone the cutting-line CB3 as depicted in FIG. 1B(1); FIG. 1B(5) is a cross-sectional view taken alone the cutting-line CB4 as depicted in FIG. 1B(1); and FIG. 1B(6) is a cross-sectional view within the peripheral circuit region 101P of the DRAM circuit structure shown in FIG. 1B(1).

Then, at least one etching processes using the recess gate pattern 114 as an etching mask is performed to remove a portion of the hard mask layer 110 to form a plurality of recesses 110O exposing portions of the pad dielectric layer 109 and the STI structure 103. A nitride layer 115 is then formed to fill the plurality of recesses 110O. And after the nitride layer 115 is etched back, the RG pattern 114 is transferred to the remaining nitride layer 115. Meanwhile, the hard mask layer 110 on the peripheral circuit region 101P of the DRAM circuit structure is protected without forming any recesses 110O. The above-mentioned processes are DRAM standard foundry flows.

As shown in FIGS. 1C(1)-1C(6), FIG. 1C(1) is a top view illustrating the structure after the RG pattern 114 is transferred to the remaining nitride layer 115; FIG. 1C(2) is a cross-sectional view taken alone the cutting-line CC1 as depicted in FIG. 1C(1); FIG. 1C(3) is a cross-sectional view taken alone the cutting-line CC2 as depicted in FIG. 1C(1); FIG. 1C(4) is a cross-sectional view taken alone the cutting-line CC3 as depicted in FIG. 1C(1); FIG. 1C(5) is a cross-sectional view taken alone the cutting-line CC4 as depicted in FIG. 1C(1); and FIG. 1C(6) is a cross-sectional view within the peripheral circuit region 101P of the DRAM circuit structure shown in FIG. 1C(1).

After pealing the remaining portion of the hard mask layer 110 and the portion of the pad dielectric layer 109 covered by the remaining portion of the hard mask layer 110, an etching process using the remaining nitride layer 115 as an etching mask is performed to remove portions of the STI structure 103, so as to form the at least one hollowed trench 104 in the shallow trenches 103T and to remain the portions of the STI structure 103 covered by the remaining nitride layer 115 (i.e. the RG pattern 114 transferred to the nitride layer 115), as shown in FIG. 1D(3) and DIG. 1D(5). Although there is no remaining STI structure 103 in the hollowed trench 104 as shown in FIG. 1D(2), in another embodiment, some STI structure 103 could be remained in the hollowed trench 104. In some embodiments of the present disclosure, each of the active areas 101A is surrounded by the hollowed trench 104.

As shown in FIGS. 1D(1)-1D(6), FIG. 1D(1) is a top view illustrating the structure after the at least one hollowed trench 104 is formed in the shallow trenches 103T; FIG. 1D(2) is a cross-sectional view taken alone the cutting-line CD1 as depicted in FIG. 1D(1); FIG. 1D(3) is a cross-sectional view taken alone the cutting-line CD2 as depicted in FIG. 1D(1); FIG. 1D(4) is a cross-sectional view taken alone the cutting-line CD3 as depicted in FIG. 1D(1); FIG. 1D(5) is a cross-sectional view taken alone the cutting-line CD4 as depicted in FIG. 1D(1); and FIG. 1D(6) is a cross-sectional view within the peripheral circuit region 101P of the DRAM circuit structure shown in FIG. 1D(1).

Referring to Sub-step S123: A dielectric layer 105 is formed on sidewalls 104S and a bottom 104B of the at least one hollowed trench 104. In some embodiments of the present disclosure, a dielectric material deposition process could be performed to form the dielectric layer 105 covering on the active region 101A, the sidewalls 104S and a bottom 104B of the at least one hollowed trench 104. In the present embodiment, the dielectric lying layer 105 is a silicon oxide film (2-3 nm) formed by a thermal oxidation to cover the portions of the semiconductor substrate 101 exposed from the at least one hollowed trench 104.

Referring to Sub-step S124: The at least one hollowed trench 104 is filled with a high thermal conductivity material to formed at least one high thermal conductivity region 106 electrically isolated from the semiconductor substrate 101 by the dielectric layer 105. The at least one high thermal conductivity region 106, the dielectric layer 105 and the remained portion of the STI structure 103 (if any) are combined to form the composite isolation structure 102 (or composite STI region) surrounding each of the active areas 101A.

As shown in FIGS. 1E(1)-1E(6), FIG. 1E(1) is a top view illustrating the structure after the at least one high thermal conductivity region 106 is formed in the at least one hollowed trench 104; FIG. 1E(2) is a cross-sectional view taken alone the cutting-line CE1 as depicted in FIG. 1E(1); FIG. 1E(3) is a cross-sectional view taken alone the cutting-line CE2 as depicted in FIG. 1E(1); FIG. 1E(4) is a cross-sectional view taken alone the cutting-line CE3 as depicted in FIG. 1E(1); FIG. 1E(5) is a cross-sectional view taken alone the cutting-line CE4 as depicted in FIG. 1E(1); and FIG. 1E(6) is a cross-sectional view within the peripheral circuit region 101P of the DRAM circuit structure shown in FIG. 1E(1).

In some embodiment of the present disclosure, the high thermal conductivity region 106 is formed by directly depositing material with a thermal conductivity greater than a thermal conductivity of silicon oxide to fill the hollowed trench 104. The high thermal conductivity region 106 may be made of material of silicon, SiC, BN, AlN or an arbitrary combination thereof.

For example, to form poly-silicon, undoped amorphous silicon could be deposited at low temperature, and then laser recrystallization could be performed against those undoped amorphous silicon to get large-grain undoped crystalline silicon or undoped poly-silicon. Thereafter, CMP process could be made on those large-grain undoped crystalline silicon for flatness.

In order to solve the gap fill problem, the forming of the high thermal conductivity region 106 includes steps as follows: Firstly, amorphous silicon is deposited on the semiconductor substrate 101 to cover the dielectric layer 105 and fill the at least one hollowed trench 104. In some embodiments of the present disclosure, a top surface of the amorphous silicon is higher than that of the dielectric layer 105 around 800 nm˜2000 nm after filling the hollowed trench 104 with the amorphous silicon.

Next, UV (ultraviolet) curing is performed against those amorphous silicon to form seamless gap-filling amorphous silicon. Then a laser annealing or a rapid thermal annealing is performed to make the amorphous silicon filled in the at least one hollowed trench 104 recrystallized to form poly-silicon, so as to improve the thermal conductivity of the high thermal conductivity region 106. The high thermal conductivity region 106 may have an average grin size ranging from 0.5 um to 2 um. Thereafter, CMP process could be made on those large-grain undoped crystalline silicon for flatness. After the CMP process, a top surface of the thermal conductivity region 106 (the thermal conductivity semiconductor material) is leveled up with that of the dielectric layer 105.

Referring to Step S13: At least one transistor 107 is formed based on the at least one the active area 101A; wherein the Step S13 for forming the at least one transistor 107 includes Sub-steps S131-S134:

Referring to Sub-step S131: At least one gate recess 108 is formed, extending into the at least one active area 101A of the semiconductor substrate 101 from the original surface 101S. The forming of the least one gate recess 108 includes steps as follows:

The high thermal conductivity region 106 is etched back to expose the active area 101A of the semiconductor substrate 101. The top level (top surface 106S) of the etched high thermal conductivity region 106 is under Si surface (such as under the original surface 101S of the semiconductor substrate 101 for 5 nm˜30 nm, for example 10 nm) to avoid leakage. Therefore, the top surface 106S of the high thermal conductivity region 106 (the thermal conductivity semiconductor material) is lower than the original surface 101S of the semiconductor substrate 101.

Then an oxide hard mask layer 116 and another amorphous carbon (a-C) layer 117 are formed in sequence to cover on the high thermal conductivity region 106 and the exposed active area 101A of the semiconductor substrate 101. The amorphous carbon (a-C) layer 117 is then planarized (e.g., by a chemical-mechanical planarization (CMP) process) using the remaining nitride layer 115 as a stop layer.

As shown in FIGS. 1F(1)-1F(6), FIG. 1F(1) is a top view illustrating the structure after the oxide hard mask layer 116 and another amorphous carbon(a-C) layer 117 are formed; FIG. 1F(2) is a cross-sectional view taken alone the cutting-line CF1 as depicted in FIG. 1F(1); FIG. 1F(3) is a cross-sectional view taken alone the cutting-line CF2 as depicted in FIG. 1F(1); FIG. 1F(4) is a cross-sectional view taken alone the cutting-line CF3 as depicted in FIG. 1F(1); FIG. 1F(5) is a cross-sectional view taken alone the cutting-line CF4 as depicted in FIG. 1F(1); and FIG. 1F(6) is a cross-sectional view within the peripheral circuit region 101P of the DRAM circuit structure shown in FIG. 1F(1).

At least one etching process using the combination of the oxide hard mask layer 116 and the a-C layer 117 as an etching mask to remove the remaining nitride layer 115, the patterned pad dielectric layer 109, a portion of the semiconductor substrate 101 and a portion of the STI structure 103 beneath the remaining nitride layer 115 which is removed. Thereby, a plurality word line trenches 118T and a plurality of gate recesses 108 overlapping with the word line trenches 118T are formed. In the present embodiment, the plurality of word line trenches 118T expose portions of the STI structure 103 among a set of active regions 101A arranged in the memory cell circuit region of the DRAM circuit structure; and the plurality of gate recesses 108 expose portions of the set of active region 101A. It is noticed that the gate recesses 108 are respectively disposed in the word line trenches 118T; and each of the gate recesses 108 is correspondently connected to one of the word line trenches 118T.

As shown in FIGS. 1G(1)-1G(6), FIG. 1G(1) is a top view illustrating the structure after the plurality of gate recesses 108 and the plurality of word line trenches 118T are formed; FIG. 1G(2) is a cross-sectional view taken alone the cutting-line CG1 as depicted in FIG. 1G(1); FIG. 1G(3) is a cross-sectional view taken alone the cutting-line CG2 as depicted in FIG. 1G(1); FIG. 1G(4) is a cross-sectional view taken alone the cutting-line CG3 as depicted in FIG. 1G(1); FIG. 1G(5) is a cross-sectional view taken alone the cutting-line CG4 as depicted in FIG. 1G(1); and FIG. 1G(6) is a cross-sectional view within the peripheral circuit region 101P of the DRAM circuit structure shown in FIG. 1G(1).

Referring to Sub-step S132: A gate dielectric layer 107L is formed covering on a bottom and sidewalls of the gate recesses 108/the word line trenches 118T. In some embodiments of the present disclosure, the gate dielectric layer 107L is formed by a dielectric deposition process. In the present embodiment, the gate dielectric layer 107L is a silicon oxide layer formed on the portions of the semiconductor substrate 101 exposed from the gate recesses 108/the word line trenches 118T by a thermal oxidation process. In another embodiment, the gate dielectric layer 107L could be a H-K dielectric layer.

Referring to Sub-step S133: at least one gate electrode 107E is then formed in the at least one gate recess 108. In some embodiments of the present disclosure, the forming of the gate electrode 107E includes steps as follows: Firstly, a barrier/work-function layer 107F (such as, a titanium nitride (TN) layer) is formed to cover the bottom and sidewalls of the gate recesses 108/the word line trenches 118T. The gate recesses 108/the word line trenches 118T are then filled with metal material 118 (e.g. tungsten (W)) to form the gate electrode 107E in the gate recesses 108 and to form a metal connection line crosses over the set of active regions 101 and the portion of the STI structure 103 among the set of active regions 101. Next, an etching back process is performed against the metal material 118. Then, a protection layer 119, such as a silicon nitride layer, is then formed and filled in the gate recesses 108 to cover the gate electrode 107E.

In the present embodiment, the portions of the barrier/work-function layer 107F and the metal material 118 filled in each of the plurality of gate recesses 108 may serve as a gate electrode 107E; the other portions of the barrier/work-function layer 107F and the metal material 118 remained in the word line trenches 118T may serve as a word line connecting the gate electrodes 107E of the access transistors (e.g., the transistors 107) that are formed in the memory cell circuit region of the DRAM circuit structure.

Referring to Sub-step S134: a source region 107S and a drain region 107D are formed in the corresponding active area 101A. Wherein the source region 107S is adjacent to one side of gate electrode 107E; and the drain region 107D is adjacent to one side of gate electrode 107E. The gate dielectric layer 107L, the gate electrode 107E, the source region 107S and the drain region 107D formed in the same active area 101A are combined to form a transistor 107. In the present DRAM circuit structure embodiment, a plurality of access transistors of the memory cell circuit are formed in the plurality of active areas 101A respectively, and the gate electrodes 107E thereof can be connected by a corresponding word lines and arranged in an access transistor array. Thereafter, stacked capacitors (not shown) could be formed to connect the source regions 107S of the access transistors of the memory cell circuit. And a serious downstream processes, such as, a metal damascene process . . . etc., are performed to form an interaction structure (not shown), so as to form the semiconductor circuit structure 100.

FIG. 1H(1) is a top view illustrating the semiconductor circuit structure 100 is formed; FIG. 1H(2), FIG. 1H(3), FIG. 1H(4), and FIG. 1H(5) are cross-sectional view taken alone the cutting-line CH1, CH2, CH3, and CH4 respectively, as depicted in FIG. 1H(1); and FIG. 1H(6) is a cross-sectional view within the peripheral circuit region 101P of the semiconductor circuit structure (the DRAM circuit structure) not shown in FIG. 1H(1).

On the top view of the present DRAM circuit structure embodiment, as shown in FIG. 1H(1), there is a gap G between two active area 101A, and the portion of the composite isolation structure 102 (or composite STI region) disposed in the gap G can be referred as an inner section, and the other portion of the composite isolation structure 102 (or composite STI region) outside the gap G can be referred as an outer section. The inner section can be at least further divided into a first portion P1 which is not overlapped with the metal material 118 (or the word line trenches 118T) and a second portion P2 which is overlapped with the metal material 118 (or the word line trenches 118T). The metal connection line (metal material 118) can cross over the first set of active regions 101A and the second portion P2 of the inner section of the composite isolation structure 102 (or composite STI region).

In the present embodiment, the first portion P1 of the inner section of the composite isolation structure 102 (or composite STI region) includes portions of the high thermal conductivity region 106 and the dielectric layer 105 (as shown in FIG. 1H(2)). The second portion P2 of the inner section of the composite isolation structure 102 (or composite STI region) includes a portion of the STI structure 103, but does not includes the high thermal conductivity region 106 (as shown in FIG. 1H(3)).

In conventional DRAM circuit structure, the active regions of the memory cell circuit are surrounded by STI region the material of which (SiO₂) is a poor heat conductor. In the present invention, since the STI structure 103 (SiO₂) in the STI region surrounding the active regions/transistors are at least partially substituted by the high thermal conductivity region 106 with a thermal dissipation capability higher than that of the STI structure 103 (SiO₂), thus the efficiency for reducing the junction temperatures of transistors can be significantly improved. Using the present DRAM circuit structure as described above as an example, in the memory cell circuit, most of the STI structure 103 (SiO₂) in the STI region surrounding the active regions/access transistors is removed and replaced by high thermal conductivity material) as shown in FIG. 1H(6), except those STI structure 103 (SiO₂) under the word lines (as shown in FIG. 1H(2)). On the other hand, in the peripheral circuit of the DRAM, the STI structure 103 (SiO₂) in the STI region surrounding the active regions/transistors is removed and replaced by high thermal conductivity material, as shown in FIG. 1H(6). The high thermal conductivity material could be semiconductor material, such as silicon, silicon carbide (SiC), boron nitride (BN), aluminum nitride (AlN), etc. Using silicon as example, according to the proposed processes, after thermal annealing, the grain size of the silicon could be ranging from 0.1 um to 2 um. Thus, in the event the depth of the STI region is around 250 nm˜500 nm, within the STI region there could be no more than three grains of silicon (or no more than two grain boundary) along the depth direction of the STI region.

In addition, since the process and material for forming the high thermal conductivity region 106 within STI region can be provided from and integrated in the standard processing flow of the semiconductor circuit structure 100, thus the thermal dissipation capability of the semiconductor circuit structure 100 can be effectively improved without adding expensive cost.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor circuit structure comprising:
a semiconductor substrate;
a first set of active regions within the semiconductor substrate; and
a fist shallow trench isolation (STI) region surrounding the first set of the active regions;
wherein the first STI region comprises an inner section disposed within a gap among the first set of active regions and an outer section not disposed within the gap;
wherein the inner section comprises a first portion with a thermal conductivity semiconductor material and a second portion without the thermal conductivity semiconductor material, and a thermal conductivity of the thermal conductivity semiconductor material is higher than that of silicon-dioxide (SiO₂).

2. The semiconductor circuit structure according to claim 1, wherein the semiconductor substrate has an original surface, and a top surface of the thermal conductivity semiconductor material is lower than the original surface between 5 nm to 30 nm.

3. The semiconductor circuit structure according to claim 1, wherein the thermal conductivity semiconductor material comprises silicon with an average grain size ranging from 0.1 um to 2 um.

4. The semiconductor circuit structure according to claim 3, wherein within the first STI region, there is no more than three grains of silicon along a depth direction of the first STI region.

5. The semiconductor circuit structure according to claim 1, wherein the thermal conductivity semiconductor material is selected form a group consisting of silicon, silicon carbide (SiC), boron nitride (BN), aluminum nitride (AlN), and arbitrary combinations thereof.

6. The semiconductor circuit structure according to claim 5, wherein the first STI region further comprises a dielectric layer to isolate the thermal conductivity semiconductor material from the semiconductor substrate.

7. The semiconductor circuit structure according to claim 1, wherein the first portion of the inner section of the first STI region is horizontally separate from the second portion of the inner section of the first STI region, and a metal connection line crosses over the first set of active regions and the second portion of the inner section of the first STI region.

8. The semiconductor circuit structure according to claim 7, wherein the semiconductor circuit structure is a DRAM circuit comprising a memory cell circuit and a peripheral circuit, and the first set of the active regions are within the memory cell circuit; wherein an access transistor within one of the first set of the active regions comprises:
a gate recess extending into the semiconductor substrate from the original surface;
a gate dielectric layer covering on a bottom and sidewalls of the gate recess;
a gate electrode formed in the gate recess and surrounded by the gate dielectric layer;
a source region adjacent to one side of the gate electrode; and
a drain region adjacent to another side of the gate electrode.

9. The semiconductor circuit structure according to claim 8, wherein the metal connection line is a word line connected to the gate electrode of the access transistor.

10. The semiconductor circuit structure according to claim 7, wherein the peripheral circuit comprises a second set of active regions and a second STI region surrounding the second set of active regions; wherein all of the second STI region comprises the thermal conductivity semiconductor material, and all of the outer section of the first STI region comprises the thermal conductivity semiconductor material.

11. A method for fabricating a semiconductor circuit structure comprising:
providing a semiconductor substrate;
forming a fist shallow trench isolation (STI) region surrounding a first set of the active regions within the semiconductor substrate, and
forming a transistor within one of the first set of the active regions;
wherein the first STI region including an inner section disposed within a gap among the first set of active regions and an outer section not disposed within the gap among the first set of active regions;
wherein the inner section includes a first portion with a thermal conductivity semiconductor material and a second portion without the thermal conductivity semiconductor material, and a thermal conductivity of the thermal conductivity semiconductor material is higher than that of SiO₂.

12. The method according to claim 11, wherein the forming of the first STI region comprises:
forming a shallow trench extending into the semiconductor substrate from an original surface of the semiconductor substrate to define the first set of active regions;
filling an oxide structure within the shallow trench;
removing at least portion of the oxide structure in the first portion of the inner section and the outer section to form at least one hollowed trench;
forming a dielectric layer on sidewalls and a bottom of the at least one hollowed trench; and
filling the at least one hollowed trench with the thermal conductivity semiconductor material, wherein the thermal conductivity semiconductor material is isolated from the semiconductor substrate by the dielectric layer.

13. The method according to claim 12, wherein the step of filling the at least one hollowed trench with the thermal conductivity semiconductor material comprises:
filling the at least one hollowed trench with an amorphous semiconductor material;
curing the amorphous semiconductor material by an ultraviolet light; and
performing a laser annealing or a rapid thermal annealing against the cured amorphous semiconductor material to form the thermal conductivity semiconductor material.

14. The method according to claim 12, wherein the thermal conductivity semiconductor material is selected from a group consisting of Si, SiC, BN, AlN, and arbitrary combinations thereof.

15. The method according to claim 12, wherein the semiconductor circuit structure is a DRAM circuit comprising a memory cell circuit and a peripheral circuit, and the first set of the active regions are within the memory cell circuit; wherein the transistor is an access transistor within one of the first set of the active regions, wherein the forming of the access transistor comprises:
forming a gate recess extending into the one of the first set of the active regions of the semiconductor substrate from the original surface;
forming a gate dielectric layer covering on a bottom and sidewalls of the gate recess;
forming a gate electrode in the gate recess and surrounded by the gate dielectric layer; and
forming a source region adjacent to one side of the gate electrode and a drain region adjacent to another side of the gate electrode.

16. The method according to claim 15, wherein the first portion of the inner section of the first STI region is horizontally separate from the second portion of the inner section of the first STI region, and a metal connection line crosses over the first set of active regions and the second portion of the inner section of the first STI region.

17. The method according to claim 16, wherein the metal connection line is a word line connected to the gate electrode of the access transistor.

18. The method according to claim 16, wherein the peripheral circuit comprises a second set of active regions and a second STI region surrounding the second set of active regions; wherein all of the second STI region comprises the thermal conductivity semiconductor material, and all of the outer section of the first STI region comprises the thermal conductivity semiconductor material.
